(19) United States
(12) Patent Application Publication
(10) Pub. No.: US 2026/0073971 A1
(43) Pub. Date: Mar. 12, 2026

(54) SEMICONDUCTOR MEMORY DEVICE

(71) Applicant: Kioxia Corporation, Tokyo (JP)

(72) Inventor: Yuki ISHIZAKI, Odawara Kanagawa (JP)

(73) Assignee: Kioxia Corporation, Tokyo (JP)

(21) Appl. No.: 19/002,863

(22) Filed: Dec. 27, 2024

(30) Foreign Application Priority Data
Sep. 6, 2024 (JP) 2024-154060

(51) Int. Cl. G11C 11/4091; G11C 5/14; G11C 11/4096

(52) U.S. Cl. CPC G11C 11/4091; G11C 5/147; G11C 11/4096

(57) ABSTRACT

According to one embodiment, a semiconductor memory device includes a memory cell transistor; and a sense amplifier module, wherein: the sense amplifier module includes: a first node electrically couplable to a bit line; and a second node capacitively couplable with the first node; in a read operation of reading first data and second data continuously, a voltage of the second node decreases with a decrease in a voltage of the first node in a first period that is continuous to a second period; the sense amplifier module is configured to: determine the first data based on the voltage of the second node that is lowered in the first period; and determine the second data based on the voltage of the first node that is lowered in the second period.

### CROSS-REFERENCE TO RELATED APPLICATION

This application is based upon and claims the benefit of priority from prior Japanese Patent Application No. 2024-154060, filed September 6, 2024, the entire contents of which are incorporated herein by reference.

### FIELD

Embodiments described herein relate generally to a semiconductor memory device.

### BACKGROUND

NAND flash memories capable of storing data in a nonvolatile manner are known.

### BRIEF DESCRIPTION OF THE DRAWINGS

FIG. 1 is a block diagram showing an example of an overall configuration of a host device and a memory system including a semiconductor memory device according to an embodiment.

FIG. 2 is a block diagram showing an example of a configuration of the semiconductor memory device according to the embodiment.

FIG. 3 is a circuit diagram showing an example of a circuit configuration of a memory cell array provided in the semiconductor memory device according to the embodiment.

FIG. 4 is a diagram showing an example of the threshold voltage distribution of memory cell transistors provided in the semiconductor memory device according to the embodiment.

FIG. 5 is a block diagram showing an example of a configuration of a sense amplifier module provided in the semiconductor memory device according to the embodiment.

FIG. 6 is a circuit diagram showing an example of a circuit configuration of the sense amplifier module provided in the semiconductor memory device according to the embodiment.

FIG. 7 is a graph illustrating the selection of a program operation in a write operation using the semiconductor memory device according to the embodiment.

FIG. 8 is a graph illustrating a verify operation using the semiconductor memory device according to the embodiment.

FIG. 9 is a timing chart illustrating a verify operation using the semiconductor memory device according to the embodiment.

### DETAILED DESCRIPTION

In general, according to one embodiment, a semiconductor memory device includes a bit line; a memory cell transistor electrically coupled to the bit line; and a sense amplifier module which reads data from the memory cell transistor via the bit line, wherein: the sense amplifier module includes: a first node electrically couplable to the bit line; and a second node capacitively couplable with the first node; in a read operation of reading first data and second data continuously while applying a first voltage to a gate of the memory cell transistor, a voltage of the second node decreases with a decrease in a voltage of the first node by capacitive coupling between the first node and the second node in a first period that is continuous to a second period; and the sense amplifier module is configured to: determine the first data based on the voltage of the second node that is lowered in the first period; and determine the second data based on the voltage of the first node that is lowered in the second period.

An embodiment will be described below with reference to the drawings. In the following description, components having the same function and configuration are denoted by a common reference symbol. Further, when a plurality of components having a common reference code are distinguished, a subscript is attached to the common reference code to distinguish them. When a plurality of components need not be distinguished, only common reference numerals are attached to the plurality of components and no subscripts are attached. The subscript includes, for example, a lowercase letter appended to the end of the reference code, an index representing an array, and the like.

Embodiments will now be described with reference to the drawings. In the following description, components having the same function and configuration are denoted by common reference symbols. In order to distinguish a plurality of components having common reference symbols, a subscript is attached to each of the common reference symbols. Unless a plurality of components are particularly distinguished, only common reference symbols are attached to the components and no subscripts are attached thereto. The subscript includes a lowercase letter appended to the end of a reference symbol, an index representing an arrangement, and the like.

### 1 Embodiment

A memory system according to an embodiment will be described.

### 1.1 Configuration

The configuration of the memory system according to the embodiment will be described.

### 1.1.1 Memory System

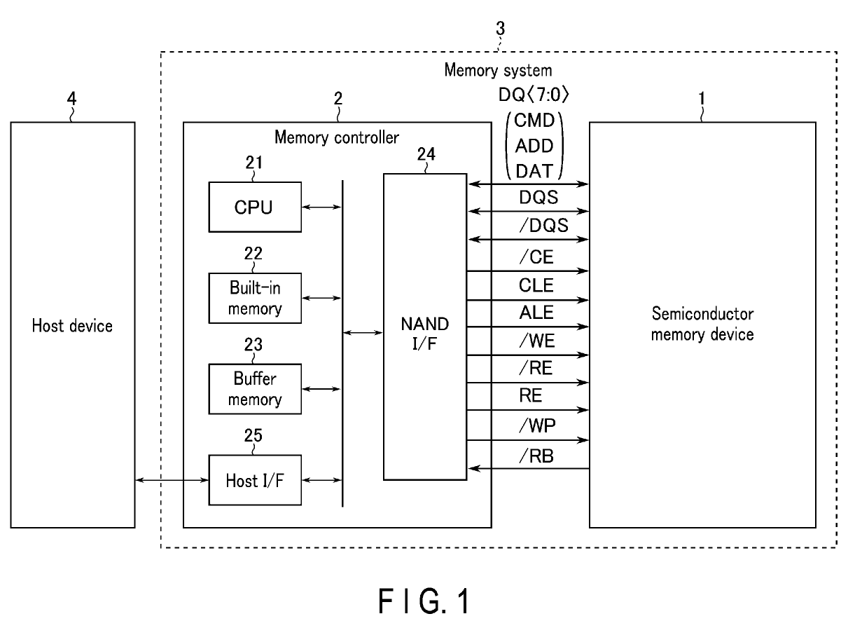

The overall configuration of the memory system according to the embodiment will be described with reference FIG. 1. FIG. 1 to is a block diagram showing an example of the overall configuration including a host device and a memory system according to the embodiment.

The memory system 3 includes a semiconductor memory device 1 and a memory controller 2. The semiconductor memory device 1 and the memory controller 2 may be combined into one semiconductor device, for example. The memory system 3 is, for example, a solid state drive (SSD) and an SD^{TM} card.

The memory system 3 communicates with an external host device 4, for example. The memory system 3 stores data from the host device 4. In addition, the memory system 3 reads data from the host device 4.

The semiconductor memory device 1 is, for example, a semiconductor memory. The semiconductor memory device 1 includes a plurality of memory cells. The semiconductor memory device 1 stores data in a nonvolatile manner. The semiconductor memory device 1 is, for example, a NAND flash memory. The semiconductor memory device 1 may also be referred to as a memory device. The semiconductor memory device 1 is coupled to the memory controller 2 via, for example, a NAND bus.

The NAND bus transmits and receives various signals through their respective signal lines in accordance with a NAND interface. The various signals include, for example, /CE, CLE, ALE, /WE, /RE, RE, /WP, /RB, DQ<7:0>, DQS and /DQS.

The signal /CE is a chip enable signal. The signal /CE is a signal for enabling the semiconductor memory device 1. The signal CLE is a command latch enable signal. The signal CLE notifies the semiconductor memory device 1 that the signal DQ<7:0> flowing through the semiconductor memory device 1 is a command while the signal CLE is at an "H (high)" level. The signal ALE is an address latch enable signal. The signal CLE notifies the semiconductor memory device 1 that the signal DQ<7:0> flowing through the semiconductor memory device 1 is an address while the signal ALE is at an "H" level. The signal /WE is a write enable signal. The signal /WE instructs the semiconductor memory device 1 to capture the signal DQ<7:0>. The signal /WE instructs the semiconductor memory device 1 to capture the signal DQ<7:0> as a command, an address or data at the rising edge of the signal /WE at a single data rate (SDR), for example. The signal /WE also instructs the semiconductor memory device 1 to capture the signal DQ<7:0> as a command or an address at the rising edge of the signal /WE at a double data rate (DDR), for example. The signal /RE is a read enable signal. The signal /RE instructs the semiconductor memory device 1 to output the signal DQ<7:0>. The signal /RE instructs the semiconductor memory device 1 to output the signal DQ<7:0> as data at the falling edge of the signal /RE at a single data rate, for example. The signal /RE also instructs the semiconductor memory device 1 to output the signal DQ<7:0> as data at the falling edge and the rising edge of the signal /RE at the double data rate. The signal RE is a complementary signal of the signal /RE. The signal /WP is a write protect signal. The signal /WP instructs the semiconductor memory device 1 to inhibit data from being written and erased. The signal /RB is a ready busy signal. The signal /RB indicates whether the semiconductor memory device 1 is in a ready state (where it accepts an instruction from outside) or in a busy state (where it accepts no instruction from outside). The signal DQ<7:0> is, for example, an 8-bit signal. The signal DQS is a data strobe signal. The signal DQS is used to control the operation timing of the semiconductor memory device 1 related to the signal DQ<7:0>. The signal DQS instructs the semiconductor memory device 1 to capture the signal DQ<7:0> as data at the falling edge and rising edge of the signal DQS at a double data rate, for example. In addition, the signal DQS is generated based on the falling edge and rising edge of the signal /RE at a double data rate, for example, and is output from the semiconductor memory device 1 together with the signal DQ<7:0> as data. The signal /DQS is a complementary signal of the signal DQS.

The signal DQ<7:0> is transmitted and received between semiconductor memory device 1 and the memory controller 2, and includes a command CMD, an address ADD and data DAT. The command CMD includes a command for causing the semiconductor memory device 1 to execute a write operation (write command), a command for causing the semiconductor memory device 1 to execute a read operation (read command), a command for causing the semiconductor memory device 1 to execute an erase operation (erase command), and the like. The data DAT includes read data and write data.

The memory controller 2 is configured by an integrated circuit such as a system-on-a-chip (SoC). The memory controller 2 receives an instruction from the host device 4. The function of each part of the memory controller 2 may be implemented by dedicated hardware, a processor that runs programs and firmware, or a combination thereof. The memory controller 2 controls the semiconductor memory device 1 based on the instruction received from the host device 4. Specifically, the memory controller 2 receives a write instruction from the host device 4 and writes data to the semiconductor memory device 1. In addition, the memory controller 2 receives a read instruction from the host device 4, reads data from the semiconductor memory device 1 and transmits it to the host device 4.

### 1. 1. 2 Memory Controller

The configuration of the memory controller 2 will be described further with reference to FIG. 1.

The memory controller 2 includes a processor (central processing unit: CPU) 21, a built-in memory 22, a buffer memory 23, a NAND I/F (NAND interface circuit) 24 and a host I/F (host interface circuit) 25.

The CPU 21 controls the operation of the entire memory controller 2. The CPU 21 issues commands for instructing the semiconductor memory device 1 to perform various operations such as a write operation, a read operation and an erase operation.

The built-in memory 22 is a semiconductor memory such as a dynamic random access memory (DRAM). The built-in memory 22 is used as a work area of the CPU 21. The built-in memory 22 stores firmware for managing the semiconductor memory device 1, various management tables, and the like.

The buffer memory 23 temporarily stores write data received from the host device 4, read data received from the semiconductor memory device 1 by the memory controller 2, and the like.

The NAND interface circuit 24 is coupled to the semiconductor memory device 1 via a NAND bus to control communication with the semiconductor memory device 1. In response to the instruction from the CPU 21, the NAND interface circuit 24 transmits the command CMD, address ADD and write data to the semiconductor memory device 1. Also, the NAND interface circuit 24 receives read data from the semiconductor memory device 1.

The host interface circuit 25 is coupled to the host device 4 via a host bus to control communication between the memory controller 2 and the host device 4. The host interface circuit 25 transfers, for example, instructions and data received from the host device 4 to the CPU 21 and the buffer memory 23, respectively.

### 1. 1. 3 Semiconductor Memory Device

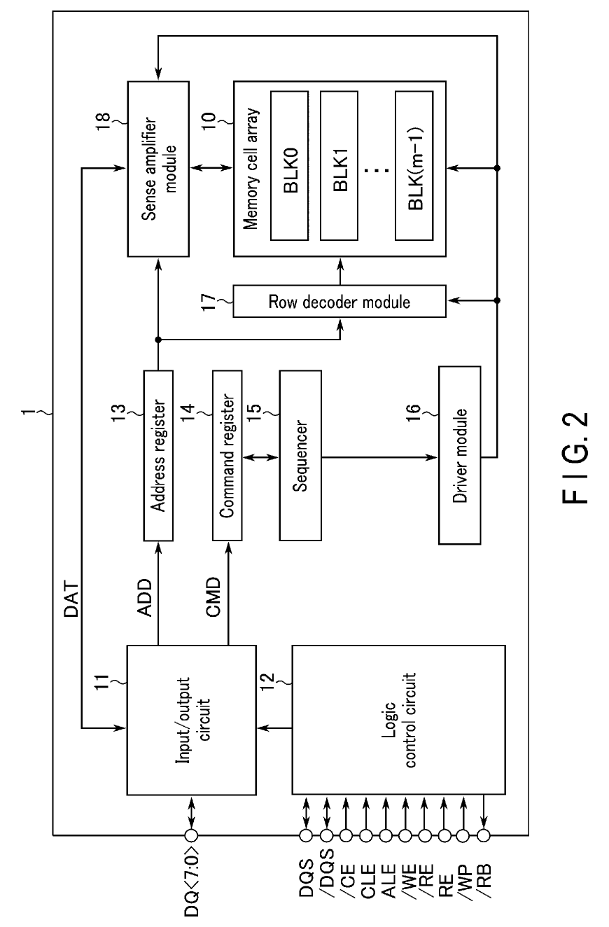

An example of a configuration of the semiconductor memory device 1 according to the embodiment will be described below with reference to FIG. 2. FIG. 2 is a block diagram showing an example of a configuration of the semiconductor memory device according to the embodiment.

The semiconductor memory device 1 includes a memory cell array 10, an input/output circuit 11, a logic control circuit 12, an address register 13, a command register 14, a sequencer 15, a driver module 16, a row decoder module 17, and a sense amplifier module 18.

The memory cell array 10 includes a plurality of blocks BLK0 to BLK(m-1), where m is an integer that is equal to or greater than 2. Each block BLK is a set of memory cell transistors capable of storing data in a nonvolatile manner. Each block BLK is used as a data erase unit, for example. That is, the data stored in the memory cell transistors included in the same block BLK are erased collectively. The configuration of the memory cell array 10 will be described in detail later.

The input/output circuit 11 transmits and receives a signal DQ<7:0> to and from the memory controller 2. The input/output circuit 11 transfers an address ADD and a command CMD in the signal DQ<7:0> to the address register 13 and the command register 14, respectively. The input/output circuit 11 also transmits and receives data DAT to and from the sense amplifier module 18.

The logic control circuit 12 receives, for example, signals /CE, CLE, ALE, /WE, /RE, RE, /WP, DQS and /DQS from the memory controller 2. The logic control circuit 12 controls the input/output circuit 11 in response to the received signals. In addition, the logic control circuit 12 generates a signal /RB and transmits it to the memory controller 2.

The address register 13 stores the address ADD transferred from the input/output circuit 11. The address register 13 transfers the stored address ADD to the row decoder module 17 and the sense amplifier module 18.

The command register 14 stores the command CMD transferred from the input/output circuit 11. The command register 14 transfers the stored command CMD to the sequencer 15.

The sequencer 15 receives the command CMD from the command register 14. The sequencer 15 controls the entire semiconductor memory device 1 in accordance with the sequence based on the received command CMD. When the sequencer 15 receives, for example, an erase command, a write command or a read command, it instructs the driver module 16 to generate a voltage to be used in an operation corresponding to the received command.

In response to the instruction from the sequencer 15, the driver module 16 generates a voltage to be used for an erase operation, a write operation, a read operation, or the like. The driver module 16 supplies the generated voltage to the row decoder module 17, the sense amplifier module 18, and the like.

The row decoder module 17 receives a block address in address ADD from the address register 13. The row decoder module 17 selects one of the blocks BLK based on the block address. The row decoder module 17 applies to the selected block BLK, for example, the voltage supplied from the driver module 16.

The sense amplifier module 18 receives a column addresses in the address ADD from the address register 13. Based on the column address, the sense amplifier module 18 transfers data DAT between the memory controller 2 and the memory cell array 10. More specifically, in write operation, the sense amplifier module 18 receives write data from the input/output circuit 11 and transfers it to the memory cell array 10. In read operation, the sense amplifier module 18 senses the threshold voltage of a memory cell transistor in the memory cell array 10, which is to be subjected to the read operation, to generate read data and then transfer it to the input/output circuit 11.

### 1. 1. 4 Memory Cell Array

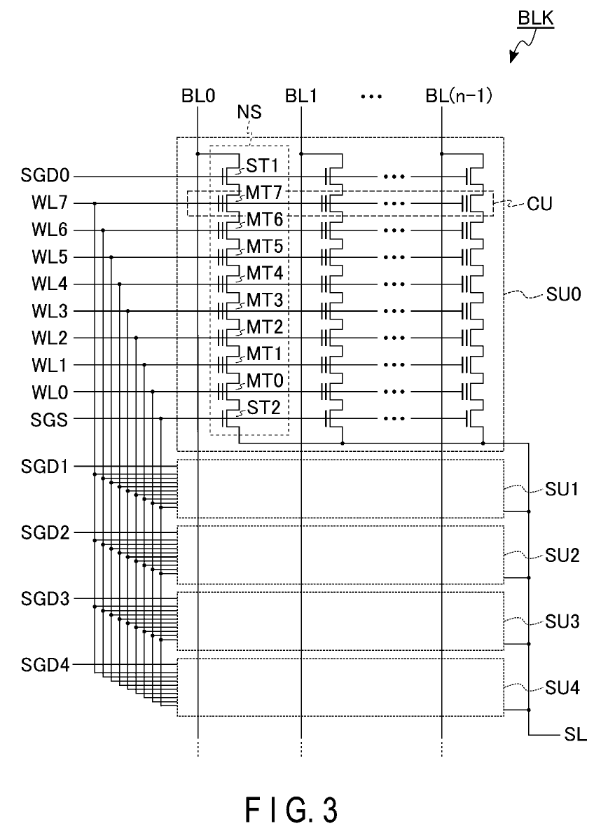

The configuration of each of the blocks BLK included in the memory cell array 10 in the semiconductor memory device 1 will be described with reference to FIG. 3. FIG. 3 is a circuit diagram showing an example of a circuit configuration of a memory cell array provided in the semiconductor memory device according to the embodiment.

The block BLK includes, for example, five string units SU0, SU1, SU2, SU3 and SU4. Hereinafter, each of the string units SU0 to SU4 will simply be referred to as a string unit SU unless the string units SU0 to SU4 are distinguished from each other. Each string unit SU includes a plurality of NAND strings NS.

Each NAND string NS includes, for example, eight memory cell transistors MT0 to MT7 and select transistors ST1 and ST2. Hereinafter, each of the memory cell transistors MT0 to MT7 will simply be referred to as a memory cell transistor MT unless the memory cell transistors MT0 to MT7 are distinguished from each other. Note that the number of memory cell transistors MT included in each NAND string NS is not limited. Each memory cell transistor MT includes a stacked gate including a control gate and a charge storage layer. The memory cell transistors MT are coupled in series between one end of the select transistor ST1 and one end of the select transistor ST2.

In each block BLK, the gates of the select transistors ST1 of the string units SU0 to SU4 are coupled to their respective select gate lines SGD0 to SGD4. That is, each select gate line SGD is coupled to only one of the string units SU in the same block BLK. The gates of the select transistors ST2 of all the string units SU in the block BLK are coupled to a select gate line SGS. That is, the select gate line SGS is coupled to all the string units SU in the same block BLK. The control gates of the memory cell transistors MT0 to MT7 in each block BLK are coupled to their respective word lines WL0 to WL7. That is, the word lines WL having the same address are coupled to all the string units SU in the same block BLK.

The other end of the select transistor ST1 is coupled to one of the bit lines BL0 to BL(n-1), where n is an integer that is equal to or greater than 2. Each bit line BL is coupled to a NAND string NS of the same column in each of the blocks BLK.

The other end of the select transistor ST2 is coupled to a source line SL. The source line SL is shared among the blocks BLK, for example.

As described above, data are erased collectively from the memory cell transistors MT in the same block BLK, for example. In contrast, the read and write operations can be performed collectively for the memory cell transistors MT coupled to any word line WL in any string unit SU of any block BLK. In the foregoing configuration, a set of memory cell transistors MT that share one word line WL in each string unit SU is referred to as a cell unit CU, for example. The cell unit CU is a set of memory cell transistors MT for which write or read operations are performed collectively. The cell unit CU corresponds to, for example, one or more sets of storage areas. A write operation or a read operation for one cell unit CU is performed for one of the sets of storage areas. A unit of such storage areas is called a "page."

### 1. 1. 5 Threshold Distribution of Memory Cell Transistors

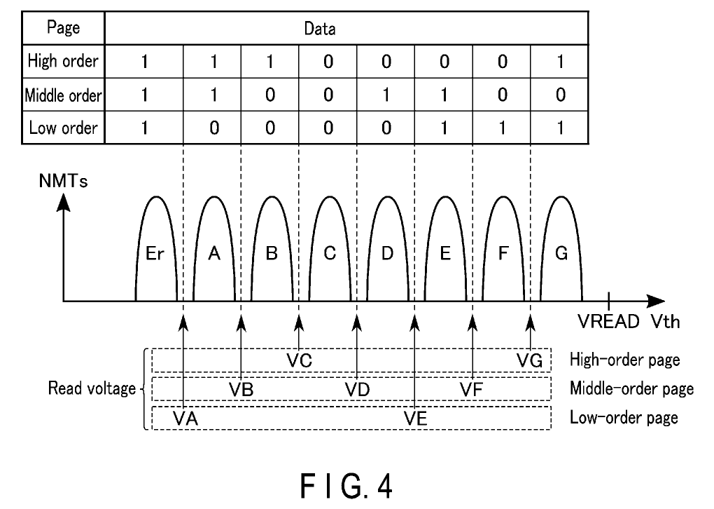

The threshold voltage distribution of the memory cell transistors MT provided in the semiconductor memory device 1 will be described with reference toFIG. 4. FIG. 4 is a diagram showing an example of the threshold voltage distribution of the memory cell transistors provided in the semiconductor memory device according to the embodiment.

In FIG. 4, the vertical axis of the threshold voltage distribution indicates the number NMTs of memory cell transistors MT. The horizontal axis indicates the threshold voltage Vth of each of the memory cell transistors MT.

In the semiconductor memory device 1 according to the embodiment, for example, eight states are formed by the threshold voltages of the memory cell transistors MT. That is, each of the memory cell transistors MT may have eight states. Hereinafter, the eight states will be referred to as "Er" state, "A" state, "B" state, "C" state, "D" state, "E" state, "F" state and "G" state in order of increasing the threshold voltage.

The "Er" state corresponds to a data erase state, for example. The threshold voltage of the memory cell transistor MT included in the "Er" state is lower than voltage VA.

The "A" to "G" states correspond to a state in which charges are injected into the charge storage layer of the memory cell transistor MT. The threshold voltage of the memory cell transistor MT included in the "A" state is equal to or higher than voltage VA and lower than voltage VB (VB > VA). The threshold voltage of the memory cell transistor MT included in the "B" state is equal to or higher than voltage VB and lower than voltage VC (VC > VB). The threshold voltage of the memory cell transistor MT included in the "C" state is equal to or higher than voltage VC and lower than voltage VD (VD > VC). The threshold voltage of the memory cell transistor MT included in the "D" state is equal to or higher than voltage VD and lower than voltage VE (VE > VD). The threshold voltage of the memory cell transistor MT included in the "E" state is equal to or higher than voltage VE and lower than voltage VF (VF > VE). The threshold voltage of the memory cell transistor MT included in the "F" state is equal to or higher than voltage VF and lower than voltage VG (VG > VF). The threshold voltage of the memory cell transistor MT included in the "G" state is equal to or higher than voltage VG and lower than voltage VREAD (VREAD > VG).

When a voltage is applied to the control gate of the memory cell transistor MT, the memory cell transistor MT is turned on if it has a threshold voltage that is lower than the applied voltage. When a voltage is applied to the control gate of the memory cell transistor MT, the memory cell transistor MT is turned off if it has a threshold voltage that is equal to or higher than the applied voltage. Note that when the voltage VREAD is applied to the control gate of the memory cell transistor MT, the memory cell transistor MT is turned on regardless of which of the states "Er" to "G" of the memory cell transistor MT.

Different 3-bit data are allocated to the above eight states. Thus, the memory cell transistor MT can hold the 3-bit data. Below is an example of allocating data to the eight states. In the example, data allocated to the respective states are shown in the order presented as follows: a high-order bit, a middle-order bit and a low-order bits.

"Er" state: "1, 1, 1" data

"A" state: "1, 1, 0" data

"B" state: "1, 0, 0" data

"C" state: "0, 0, 0" data

"D" state: "0, 1, 0" data

"E" state: "0, 1, 1" data

"F" state: "0, 0, 1" data

"G" state: "1, 0, 1" data

If the above data allocation is applied, one-page data (low-order page data) composed of low-order bits is determined by a read process using voltages VA and VE. One page data (middle-order page data) composed of middle-order bits is determined by a read process using voltages VB, VD and VF. One-page data (high-order page data) composed of high-order bits is determined by a read process using voltages VC and VG. Hereinafter, each of the voltages VA to VG will also be referred to as a read voltage.

Note that the number of states formed by the threshold voltages of a plurality of memory cell transistors MT is not limited to eight. The number may be, for example, 2, 4 and 16 or more.

### 1. 1. 6 Sense Amplifier Module

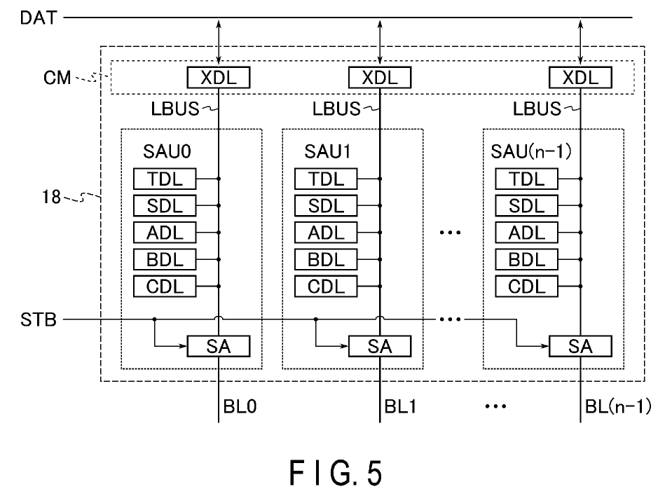

The configuration of the sense amplifier module 18 in the semiconductor memory device 1 will be described with reference to FIG. 5. FIG. 5 is a block diagram showing an example of a configuration of a sense amplifier module provided in the semiconductor memory device according to the embodiment.

The sense amplifier module 18 includes a plurality of sense amplifier units SAU0 to SAU(n-1) and a plurality of latch circuits XDL. The sense amplifier units SAU0 to SAU(n-1) are provided to correspond to their respective bit lines BL. Hereinafter, each of the sense amplifier units SAU0 to SAU(n-1) will simply be referred to as a sense amplifier unit SAU unless the sense amplifier units SAU0 to SAU(n-1) are distinguished from each other. The latch circuits XDL are provided to correspond to their respective bit lines BL and their respective sense amplifier units SAU0 to SAU(n-1).

Each sense amplifier unit SAU includes, for example, latch circuits TDL, SDL, ADL, BDL and CDL and a sense circuit SA. These latch circuits TDL, SDL, ADL, BDL and CDL and sense circuit SA are coupled to each other via a bus LBUS corresponding to the sense amplifier unit SAU. A latch circuit XDL corresponding to the sense amplifier unit SAU is coupled to the latch circuits TDL, SDL, ADL, BDL and CDL and the sense circuit SA via the bus LBUS. With this configuration, the latch circuits TDL, SDL, ADL, BDL and CDL and sense circuit SA included in the sense amplifier unit SAU and the latch circuit XDL corresponding to the sense amplifier unit SAU are coupled to each other via the bus LBUS so as to transmit and receive data.

The latch circuit XDL is used, for example, to transfer data DAT between the sense amplifier unit SAU and the input/output circuit 11.

The latch circuits TDL, SDL, ADL, BDL and CDL store, for example, write data or read data temporarily. The configurations of the latch circuits TDL, SDL, ADL, BDL and CDL will be described in more detail later.

In read operation, the sense circuit SA senses the threshold voltage of the memory cell transistor MT based on the current flowing in the bit line BL. In write operation, the sense circuit SA applies a voltage to the bit line BL in accordance with write data. In addition, the sense circuit SA performs a variety of operations using data stored in the latch circuits TDL, SDL, ADL, BDL, CDL and XDL.

### 1. 1. 7 Sense Amplifier Unit

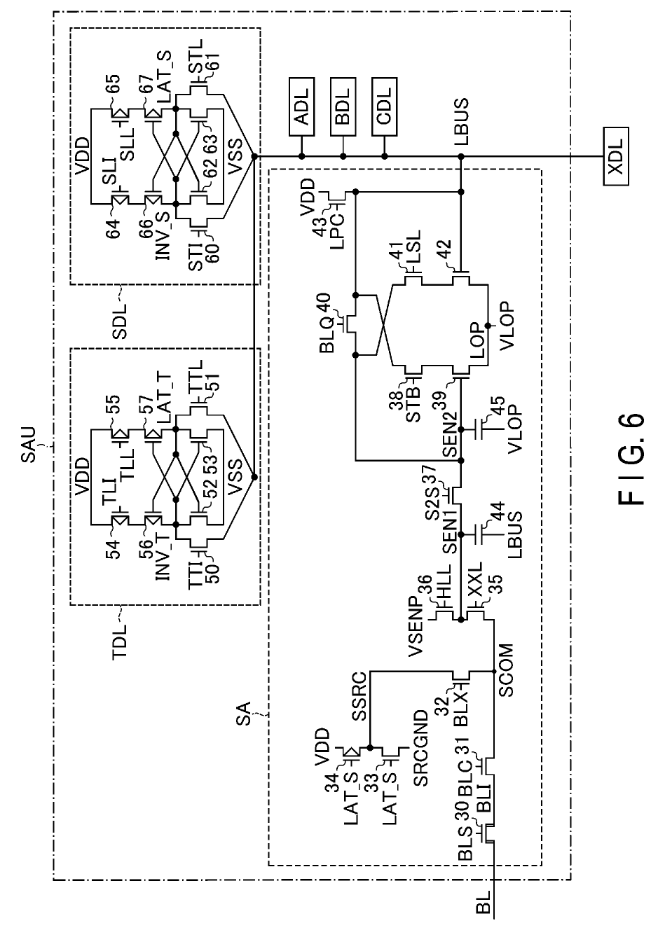

An example of the circuit configuration of the sense amplifier unit SAU will be described with reference to FIG. 6. FIG. 6 is a circuit diagram showing an example of a circuit configuration of a sense amplifier module provided in the semiconductor memory device according to the embodiment. In FIG. 6, the circuit configuration of one sense amplifier unit SAU in the sense amplifier module 18 is shown together with the latch circuit XDL. Hereinafter, one of the source and drain of the transistor will referred to as "one end of the transistor" and the other thereof will be referred to as "the other end of the transistor."

First is a description of the configuration of the sense circuit SA.

The sense circuit SA includes transistors 30 to 43 and capacitances 44 and 45. The transistor 30 is, for example, an high withstand voltage n-channel metal-oxide-semiconductor (MOS) transistor. The transistor 31 to 43 are, for example, low withstand voltage p-channel MOS transistors. The capacitance 44 is, for example, a capacitance between different interconnects, as will be described later. However, the capacitance 44 may be a capacitive element such as a MOS capacitor. The capacitance 45 is a capacitive element such as a MOS capacitor.

One end of the transistor 30 is coupled to a bit line BL, and the other end thereof is coupled to a node BLI. The gate of the transistor 30 is supplied with a signal BLS.

One end of the transistor 31 is coupled to the node BLI, and the other end thereof is coupled to a node SCOM. The gate of the transistor 31 is supplied with a signal BLC. The transistor 31 is provided to clamp the bit line BL corresponding to the transistor 31 to a voltage corresponding to the signal BLC.

One end of the transistor 32 is coupled to the node SCOM, and the other end thereof is coupled to a node SSRC. The gate of the transistor 32 is supplied with a signal BLX.

One end of the transistor 33 is coupled to the node SSRC, and the other end thereof is coupled to a node SRCGND. For example, a voltage VSS is applied to the node SRCGND. The voltage VSS is a ground voltage, for example. The gate of the transistor 33 is coupled to a node LAT_S.

A voltage VDD is applied to one end of the transistor 34 from a power supply. The other end of the transistor 34 is coupled to the node SSRC. The gate of the transistor 34 is coupled to the node LAT_S.

One end of the transistor 35 is coupled to the node SCOM, and the other end thereof is coupled to a node SEN1. The gate of the transistor 35 is supplied with a signal XXL.

A voltage VSENP is applied to one end of the transistor 36. The other end of the transistor 36 is coupled to the node SEN1. The gate of the transistor 36 is supplied with a signal HLL.

One end of the transistor 37 is coupled to the node SEN1, and the other end thereof is coupled to a node SEN2. The gate of the transistor 37 is supplied with a signal S2S.

One end of the transistor 38 is coupled to a bus LBUS. The gate of the transistor 38 is supplied with a signal STB.

One end of the transistor 39 is coupled to the other end of the transistor 38, and the other end thereof is coupled to a node LOP. A voltage VLOP is applied to the node LOP from the power supply. The gate of the transistor 39 is coupled to the node SEN2.

One end of the transistor 40 is coupled to the bus LBUS, and the other end thereof is coupled to the node SEN2. The gate of the transistor 40 is supplied with a signal BLQ.

One end of the transistor 41 is coupled to the node SEN2. The gate of the transistor 41 is supplied with a signal LSL.

One end of the transistor 42 is coupled to the other end of the transistor 41, and the other end thereof is coupled to the node LOP. The gate of the transistor 42 is coupled to the bus LBUS.

A voltage VDD is applied to one end of the transistor 43 from the power supply. The other end of the transistor 43 is coupled to the bus LBUS. The gate of the transistor 43 is supplied with a signal LPC.

The configurations of the latch circuits TDL, SDL, ADL, BDL and CDL will be described below with reference to FIG. 6. The circuit configurations of the latch circuits TDL, SDL, ADL, BDL and CDL are substantially similar to one another. For this reason, FIG. 6 shows circuit configurations of the latch circuits TDL and SDL only.

The circuit configuration of the latch circuit TDL will be described.

The latch circuit TDL includes transistors 50 to 57. The transistor 50 to 53 are low withstand voltage n-channel MOS transistors. The transistors 54 to 57 are low withstand voltage p-channel MOS transistors.

One end of the transistor 50 is coupled to a node INV_T, and the other end thereof is coupled to the bus LBUS. The gate of the transistor 50 is supplied with a signal TTI.

One end of the transistor 51 is coupled to a node LAT_T, and the other end thereof is coupled to the bus LBUS. The gate of the transistor 51 is supplied with a signal TTL.

One end of the transistor 52 is coupled to the node INV_T. A voltage VSS is applied to the other end of the transistor 52. The gate of the transistor 52 is coupled to the node LAT_T.

One end of the transistor 53 is coupled to the node LAT_T, and the other end thereof is coupled to the other end of the transistor 52. Accordingly, a voltage VSS is applied to the other end of the transistor 53 as well as the other end of the transistor 52. The gate of the transistor 53 is coupled to the node INV_T.

A voltage VDD is applied to one end of the transistor 54 from the power supply. The gate of the transistor 54 is supplied with a signal TLI.

One end of the transistor 55 is coupled to one end of the transistor 54. Thus, a voltage VDD is applied to one end of the transistor 55 as well as the one end of the transistor 54. The gate of the transistor 55 is supplied with a signal TLL.

One end of the transistor 56 is coupled to the other end of the transistor 54, and the other end thereof is coupled to the node INV_T. The gate of the transistor 56 is coupled to the node LAT_T.

One end of the transistor 57 is coupled to the other end of the transistor 55. The other end of the transistor 57 is coupled to the node LAT_T. The gate of the transistor 57 is coupled to the node INV_T.

In the latch circuit TDL, the transistors 53 and 57 constitute a first inverter. The transistors 52 and 56 constitute a second inverter. The output of the first inverter and the input of the second inverter (voltage of the node LAT_T) are coupled to the bus LBUS via the transistor 51 for data transfer. The input of the first inverter and the output of the second inverter (voltage of the node INV_T) are coupled to the bus LBUS via the transistor 50 for data transfer. The latch circuit TDL stores data which are mutually inverted at their respective nodes LAT_T and INV_T.

The latch circuit SDL includes transistors 60 to 67. The transistor 60 to 67 correspond to the transistors 50 to 57, respectively. The signals STI, STL, SLI and SLL correspond to the signals TTI, TTL, TLI and TLL, respectively. The nodes INV_S and LAT_S correspond to the nodes INV_T and LAT_T, respectively. As described above, the circuit configurations of the latch circuits TDL, SDL, ADL, BDL and CDL are substantially equivalent to one another. A specific description of the circuit configuration of the latch circuit SDL is therefore omitted.

Various signals in the sense amplifier unit SAU described above are input, for example, under the control of the sequencer 15.

### 1. 2 Operation

An operation using the semiconductor memory device 1 according to the embodiment will be described. A write operation using the semiconductor memory device 1 according to the embodiment will be described below.

First, an overview of the write operation in the embodiment will be described.

The write operation includes a program operation and a verify operation. The programmed operation is an operation of injecting electrons into a charge storage layer to increase a threshold voltage or inhibiting the injection to maintain a threshold voltage. The verify operation is an operation of reading data after the program operation to determine whether the threshold voltage of the memory cell transistor MT has reached a target voltage. Hereinafter, the target voltage will also be referred to as a target level. The target level is set to a voltage VA, VB, VC, VD, VE, VF, VG, or the like. The semiconductor memory device 1 increases the threshold voltage of the memory cell transistor MT to a target level by combining the program and verify operations repeatedly.

### 1. 2. 1 Selection of Program Operation

In the write operation according to the embodiment, the operation and conditions to be applied in the next program operation are selected according to a result of the determination of the verify operation.

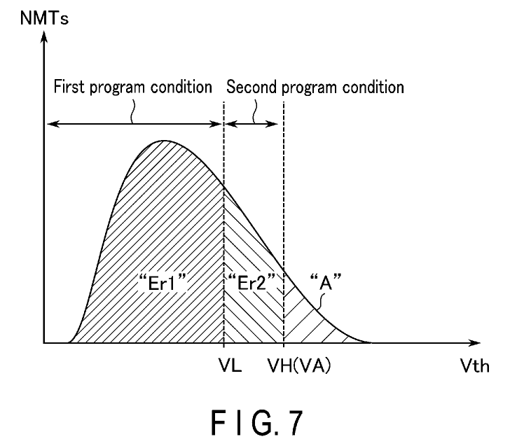

The selection of a program operation in a write operation using the semiconductor memory device 1 according to the embodiment will be described below with reference to FIG. 7. FIG. 7 is a graph illustrating the selection of a program operation in the write operation using a semiconductor memory device according to the embodiment. FIG. 7 shows an example of a distribution of threshold voltages in the process of writing from the "Er" state to the "A" state of the memory cell transistor MT whose target level is voltage VA.

Hereinafter, the operation of increasing the threshold voltage will be referred to as a "0" program operation. The operation of maintaining the threshold voltage will be referred to as a "1" program operation or a write inhibit operation.

In the "0" program operation, in accordance with a difference between the target level and the threshold voltage of the memory cell transistor MT, either a first program condition in which the amount of increase of the threshold voltage is relatively large or a second program condition in which it is smaller than that in the first program condition is applied.

If it is assumed that the threshold voltage of the memory cell transistor MT is sufficiently lower than the target level and does not reach a target level in the next program operation, the first program condition is applied. If it is assumed that the threshold voltage of the memory cell transistor MT is relatively close to a target level and greatly exceeds the target level when the first program condition is applied in the next program operation, the second program condition is applied.

When the threshold voltage of the memory cell transistor MT is equal to or higher than the voltage VH, the "1" program operation is applied to the memory cell transistor MT. When it is lower than the voltage VH, the "0" program operation is applied thereto. Note that in the example of FIG. 7, the voltage VH is equal to the voltage VA, for example. In addition, if the memory cell transistor MT has the "A" state, the "1" program operation is applied. If the memory cell transistor MT has the "Er" state, the "0" program operation is applied.

If the "0" program operation is applied, the semiconductor memory device 1 determines which of the first and second program conditions is applied. In this determination, for example, a voltage VL that is lower than the voltage VH may be set. Thus, if the threshold voltage of the memory cell transistor MT is lower than the voltage VL, the first program condition is applied to the memory cell transistor MT in the next program operation. InFIG. 6, a state in which the threshold voltage of the memory cell transistor MT is lower than the voltage VL is shown as an "Er1" state. If the threshold voltage of the memory cell transistor MT is equal to or higher than the voltage VL and lower than the voltage VH, the second program condition is applied to the memory cell transistor MT in the next program operation. In FIG. 6, a state in which the threshold voltage of the memory cell transistor MT is equal to or higher than the voltage VL and lower than the voltage VH is shown as an "Er2" state.

### 1. 2. 2 Verify Operation

Next is a description of a verify operation in the embodiment.

### 1. 2. 2. 1 Overview

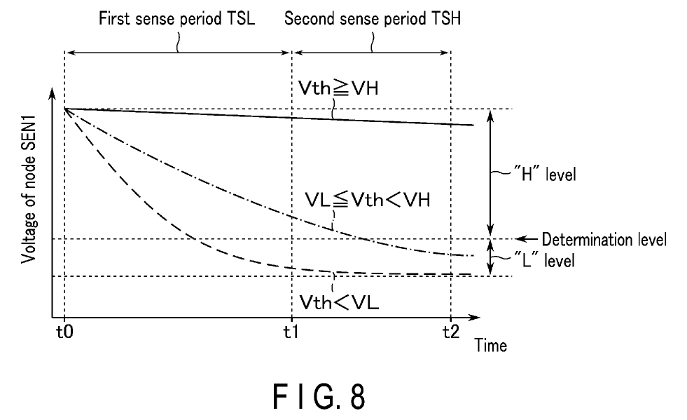

First, an overview of the verify operation in the embodiment will be described with reference to FIG. 8. FIG. 8is a graph illustrating a verify operation using the semiconductor memory device according to the embodiment.

The verify operation in the embodiment includes a first sense operation and a second sense operation. The first sense operation is an operation of determining whether to apply a first program condition of the "0" program operation in the next program operation. The second sense operation is an operation of determining whether to apply the "1" program operation or to apply a second program condition of the "0" program operation to a memory cell transistor MT to which the first program condition of the "0" program operation is not to be applied in the next program operation. As described above, the semiconductor memory device 1 according to the embodiment determines which of the "0" and "1" program operations is to be applied in the next program operation and determines which of the first and second program conditions is to be applied when the "0" program operation is applied.

That is, the first sense operation corresponds to a determination as to whether the threshold voltage of the memory cell transistor MT has reached the voltage VL. The second sense operation corresponding to a determination as to whether the threshold voltage of the memory cell transistor MT whose threshold voltage has reached the voltage VL has reached the voltage VH.

In FIG. 8, the voltage of the node SEN1 corresponding to the memory cell transistor MT for which the "1" program operation is operated is indicated by a solid line. The voltage of the node SEN1 corresponding to the memory cell transistor MT for which the "0" program operation to which the first program condition is applied is performed, is indicated by a broken line. In addition, the voltage of the node SEN1 corresponding to the memory cell transistor MT for which the "0" program operation to which the second program condition is applied is performed, is indicated by a one-dot-one-dash line.

According to the embodiment, in the verify operation, the charge of the node SEN1 is transferred to the bit line BL while the voltage VH is applied to the word line WL. In the verify operation, the nodes SEN1 and SEN2 are, for example, at substantially the same node. A first sense period TSL from time t0 to time t1 corresponds to the first sense operation and a second sense period TSH from time t1 to time t2 corresponds to the second sense operation. Hereinafter, each of the first sense period TSL and second sense period TSH will also be referred to simply as a sense period unless the first sense period TSL and the second sense period TSH are distinguished from each other.

If the charge of the node SEN1 is transferred to the bit line BL in the sense period, the voltage of the node SEN1 lowers. The speed at which the voltage of the node SEN1 lowers varies with the threshold voltage Vth of the memory cell transistor MT. If the threshold voltage Vth is, for example, lower than the voltage VL (Vth < VL), the memory cell transistor MT is strongly turned on. Accordingly, the voltage of the node SEN1 (broken line in FIG. 8) lowers rapidly. If the threshold voltage Vth is equal to or higher than the voltage VL and less than the voltage VH (VL ≤ Vth < VH), the memory cell transistor MT is weakly turned on. Accordingly, the voltage of the node SEN1 (dashed line in FIG. 8) is gradually lowered. If the threshold voltage Vth is equal to or higher than the voltage VH (Vth ≥ VH), the memory cell transistor MT is turned off. Thus, the voltage of the node SEN1 (solid line in FIG. 8 ) hardly lowers.

Based on the relationship described above, the length of the first sense period TSL is set such that the voltage of the node SEN1 corresponding to a memory cell transistor MT whose threshold voltage Vth is lower than the voltage VL becomes equal to or lower than a predetermined determination level and the voltage of the node SEN1 corresponding to a memory cell transistor MT whose threshold voltage Vth is equal to or higher than the voltage VL becomes higher than the determination level. The length of the second sense period TSH is set such that the voltage of the node SEN1 corresponding to a memory cell transistor MT whose threshold voltage Vth is lower than the voltage VH becomes equal to or lower than the determination level and the voltage of the node SEN1 corresponding to a memory cell transistor MT whose threshold voltage Vth is equal to or higher than the voltage VH becomes higher than the determination level. The predetermined determination level is, for example, a threshold voltage of the transistor 39 in the sense amplifier unit SAU shown in FIG. 6. Note that in the verify operation, for example, the transistor 37 is turned on. Thus, in the verify operation, for example, the voltages of the nodes SEN1 and SEN2 are equal to each other. Therefore, whether or not the voltage of the node SEN1 becomes higher than the determination level corresponds to whether or not the transistor 39 is turned on in response to the voltages of the nodes SEN1 and SEN2.

The sense amplifier module 18 determines whether the voltage of the node SEN1 becomes equal to or lower than the determination level at the end of the first sense period TSL and before the second sense period TSH. The sense amplifier module 18 can thus determine whether the threshold voltage Vth of the memory cell transistor MT is lower than the voltage VL in the verify operation in which the voltage VH is applied to the word line WL. That is, the sense amplifier module 18 can determine whether to apply the "0" program operation of the first program condition. At the end of the second sense period TSH, the sense amplifier module 18 again determines whether the voltage of the node SEN1 becomes equal to or lower than the determination level. The sense amplifier module 18 can thus determine whether the threshold voltage Vth of the memory cell transistor MT, which is determined to be equal to or higher than the voltage VL by the first sense operation, is lower than the voltage VH. That is, the sense amplifier module 18 can determine whether to apply the "0" program operation of the second program condition or the "1" program operation.

### 1. 2. 2. 2 Timing Chart

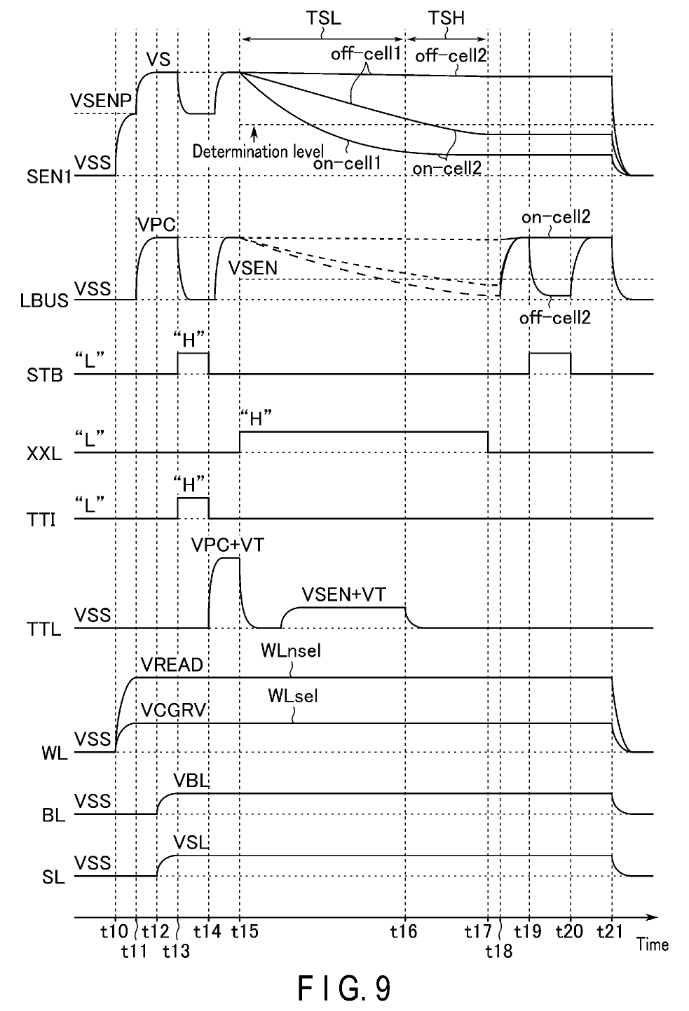

The voltage of each interconnect in the verify operation will be described with reference toFIG. 9. FIG. 9 is a timing chart illustrating a verify operation using the semiconductor memory device according to the embodiment. FIG. 9 shows voltages of the source line SL, bit line BL, word line WL, signals TTI, TTL, XXL and STB, bus LBUS and node SEN1.

Hereinafter, the memory cell transistor MT for which a write operation is performed will also be referred to as a selected memory cell transistor MT. The memory cell transistor MT for which no write operation is performed will also be referred to as a non-selected memory cell transistor MT. In addition, the word line WL corresponding to the selected memory cell transistor MT will also be referred to as a selected word line WLsel. The word line WL corresponding to the non-selected memory cell transistor MT will also be referred to as a non-selected word line WLnsel.

At time t10, the row decoder module 17 applies a voltage VCGRV to the selected word line WLsel. The row decoder module 17 also applies a voltage VREAD to the non-selected word line WLnsel. The voltage VCGRV corresponds to the voltage VH, for example. In addition, the row decoder module 17 turns on the select transistors ST1 and ST2.

At time t10, the sequencer 15 sets the signal HLL at, for example, an "H" level to turn on the transistor 36. Accordingly, the voltage of the node SEN1 rises from the voltage VSS to the voltage VSENP.

At time t11, the sequencer 15 sets the signal LPC at, for example, an "H" level to turn on the transistor 43. Accordingly, the voltage of the bus LBUS rises from the voltage VSS to the voltage VPC. Note that the voltage VPC is lower than the voltage VDD (VPC < VDD). Thus, the sense amplifier module 18 charges the bus LBUS. That is, the sense amplifier module 18 performs LBUS precharge. In addition, as a result of the rise in voltage of the bus LBUS, the voltage of the node SEN1 rises from the voltage VSENP to the voltage VS due to the effect of capacitive coupling. (VS > VSENP).

At time t12, the sense amplifier module 18 charges the bit line BL. That is, the sense amplifier module 18 performs BL precharge. With the foregoing process, the voltage of the bit line BL rises from the voltage VSS to the voltage VBL. In addition, the driver module 16 applies, for example, a voltage VSL to the source line SL.

At time t13, the sequencer 15 rises the signal TTI from an "L" level to an "H" level. Accordingly, the transistor 50 changes from off state to on state. The sequencer 15 sets the signal STB from an "L" level to an "H" level. Accordingly, the transistor 38 changes from off state to on state. As described above, the voltage of the node SEN1 is set at the voltage VS. That is, the voltage of the node SEN1 is higher than a determination level. Accordingly, the transistor 39 is turned on. For this reason, while the signals TTI and STB are set to an "H" level, the bus LBUS is brought into conduction with the node LOP, with the result that the voltage of the bus LBUS lowers to the voltage VSS, for example. Thus, the latch circuit TDL stores "1" data.

At time t14, the sequencer 15 changes the signals TTI and STB from an "H" level to an "L" level. Then, for example, the sense amplifier module 18 sets the voltage of the signal TTL from the voltage VSS to a voltage obtained by adding the threshold voltage VT of the transistor 51 to the voltage VPC (VPC + VT), thereby performing LBUS precharge again. Accordingly, the voltage of the node SEN1 rises to the voltage VS as the voltage of the bus LBUS rises.

At time t15, the sense amplifier module 18 changes the voltage of the signal TTL from the voltage (VPC + VT) to voltage VSS.

In the period of time t15 to t17, the sequencer 15 performs the first and second sense operations. The period of time t15 to t16 corresponds to the first sense period TSL. The period of time t16 to t17 corresponds to the second sense period TSH.

At time t15, the sequencer 15 changes, for example, the voltage of the signal TTL from a voltage (VPC + VT) to the voltage VSS. Accordingly, the bus LBUS is brought into a floating state. InFIG. 9, the voltage of the bus LBUS in the floating state in the first and second sense operations is indicated by a broken line. Then, the sequencer 15 sets, for example, the voltage of the signal TTL from the voltage VSS to a voltage obtained by adding the threshold voltage VT to the voltage VSEN (VSEN + VT). Thus, when the voltage of the bus LBUS becomes equal to or lower than the voltage VSEN, the transistor 51 is changed from off state to on state. While the voltage of the bus LBUS is maintained at a voltage that is higher than the voltage VSEN, the transistor 51 is maintained in an off state. The voltage VSEN corresponds to the voltage of the bus LBUS when the voltage of the node SEN1 is at the determination level in capacitive coupling between the node SEN1 and the bus LBUS.

In the period of time t15 to t17, the sequencer 15 sets the signal XXL to an "H" level. Accordingly, the transistor 35 is turned on in the period of time t15 to time t17. In this state, when the threshold voltage of the memory cell transistor MT that is a verify operation target is equal to or higher than the voltage VH, the memory cell transistor MT is turned off. Thus, almost no current flows from the bit line BL corresponding to the memory cell transistor MT to the source line SL. When the threshold voltage of the memory cell transistor MT is equal to or higher than the voltage VL and lower than the voltage VH, the memory cell transistor MT is brought into a weak on state. In this case, only a small amount of current flows from the bit line BL corresponding to the memory cell transistor MT to the source line SL.

From the above, in the period of time t15 to time t16, when the threshold voltage of the memory cell transistor MT is equal to or higher than the voltage VL (off-cell 1 in FIG. 9), the charges filled in the node SEN1 are hardly discharged. Thus, the bus LBUS in the floating state hardly changes like the node SEN1. Therefore, the data stored in the latch circuit TDL is maintained as "1" data by keeping the transistor 51 in an off state. When the threshold voltage of the memory cell transistor MT that is a verify operation target is lower than the voltage VL (on-cell 1 in FIG. 9), the memory cell transistor MT is strongly turned on, and a current significantly flows from the corresponding bit line BL to the source line SL. Accordingly, the voltage of the node SEN1 becomes equal to or lower than the determination level. In addition, the voltage of the bus LBUS becomes equal to or lower than the voltage VSEN due to the effect of the capacitive coupling between the node SEN1 and the bus LBUS in the floating state. The transistor 51 thus changes from the off state to the on state. Therefore, the data stored in the latch circuit TDL changes from "1" data to "0" data. While the transistor 51 is in the ON state, the bus LBUS is brought into conduction with the latch circuit TDL, but in FIG. 9, the voltage of the bus LBUS is indicated by not a solid line but a broken line instead of a solid line for the sake of simplicity of drawing.

At time t16, the sequencer 15 changes, for example, the voltage of the signal TTL from the voltage (VSEN + VT) to the voltage VSS. Thus, the transistor 51 is turned off regardless of the data stored in the latch circuit TDL. That is, the bus LBUS is brought into a floating state regardless of the data stored in the latch circuit TDL. , As described above, the result of determination as to whether the threshold voltage of the memory cell transistor MT reaches the voltage VL is stored in the latch circuit TDL.

In the period of time t16 to time t17, when the threshold voltage of the memory cell transistor MT is equal to or higher than the voltage VH (off-cell 2 in FIG. 9), the charges filled in the node SEN1 are hardly discharged. When the threshold voltage of the memory cell transistor MT that is a verify operation target is lower than the voltage VH (on-cell 2 in FIG. 9), a current flows from the bit line BL corresponding to the memory cell transistor MT in the on state to the source line SL, with the result that the voltage of the node SEN1 becomes equal to or lower than the determination level. The voltage of the bus LBUS becomes equal to or lower than the voltage VSEN due to the effect of capacitive coupling between the node SEN1 and the bus LBUS in the floating state. Note that the voltage of the signal TTL is set at the voltage VSS and thus the transistor 51 is maintained in an off state. The data of the latch circuit TDL is therefore maintained.

At time t17, the sequencer 15 changes the signal XXL from an "H" level to an "L" level. Accordingly, the transistor 35 changes from the on state to the off state.

At time t18, for example, the sense amplifier module 18 performs LBUS precharge. Thus, the voltage of the bus LBUS does not depend on the voltage of the node SEN1 corresponding to the bus LBUS but corresponds to the voltage VPC, for example.

At time t19, the sequencer 15 changes the signal STB from an "L" level to an "H" level. The transistor 38 is thus turned on and accordingly the voltage of the node SEN1 is strobed. When the voltage of the node SEN1 is higher than the determination level (off-cell 2 in FIG. 9), the transistor 39 is turned on. The bus LBUS is thus brought into conduction with the node LOP and accordingly the voltage of the bus LBUS lowers to, for example, the voltage VLOP. Note that in the verify operation, the voltage VLOP is lower than the voltage VSEN. On the other hand, when the voltage of the node SEN1 is equal to or lower than the determination level (on-cell 2 in FIG. 9), the transistor 39 is turned off. Accordingly, the voltage of the bus LBUS is maintained.

In the period of time t19 to t20, data based on the voltage of the bus LBUS is stored in a latch circuit different from the latch circuit TDL. The data based on the voltage of the bus LBUS is stored in the latch circuit SDL, for example. More specifically, in storing data in the latch circuit SDL, the sequencer 15 sets the signal STI at an "H" level, for example. Thus, "0" data is stored in the latch circuit SDL corresponding to the on-cell2 in FIG. 9. "1" data is stored in the latch circuit SDL corresponding to the off-cell2 in FIG. 9. Accordingly, a result of whether the threshold voltage of the memory cell transistor MT has reached the voltage VH is stored in the latch circuit SDL.

At time t20, for example, the sense amplifier module 18 performs LBUS precharge.

At time t21, a recovery process is performed. Thus, the voltage of each interconnect is set at the voltage VSS, for example.

The sense amplifier module 18 uses data stored in each of the latch circuits TDL and SDL to determine a program operation and a program condition in accordance with a difference between a target level and the threshold voltage of the memory cell transistor MT. Thus, in the next program operation, a first program condition of a "0" program operation, a second program condition of the "0" program operation or a "1" program operation is applied.

Thus, the verify operation is terminated.

### 1. 3 Advantageous Effects

According to the embodiment, the operating speed of the semiconductor memory device 1 can be improved. The advantageous effects of the embodiment will be described below.

The semiconductor memory device 1 according to the embodiment includes a bit line BL, a memory cell transistor MT and a sense amplifier module 18. The sense amplifier module 18 reads data from the memory cell transistor MT via the bit line BL. The sense amplifier module 18 includes a node SEN1 electrically couplable to the bit line BL and a bus LBUS capacitively coupled to the node SEN1. The sense amplifier module 18 is configured to determine first data based on the voltage of the bus LBUS which is lowered in a first sense period TSL by capacitive coupling of the node SEN1 and the bus LBUS and to determine second data based on the voltage of the node SEN1 which is lowered in a second sense period TSH continuous with the first sense period TSL, in a verify operation of continuously reading the first data and the second data while applying a voltage VCGRV to the gate of the memory cell transistor MT. This configuration can improve the write speed of the semiconductor memory device 1.

In addition, if the bus LBUS is not brought into a floating state in the sense operation in the verify operation (in the case of the comparative example), it is not influenced by capacitive coupling with the node (sense node) in the sense circuit. Thus, the voltage of the bus LBUS does not vary with the voltage of the sense node. In the comparative example, therefore, the voltage strobe of the sense node is executed twice in order to store the result ("0" data or "1" data) of each of the first and second sense operations in the latch circuit. In each strobe, the voltage of the bus is lowered from an "H" level to an "L" level or maintained at an "H" level. In the comparative example, therefore, for example, a reset process is performed to set the voltage of the bus LBUS at an "H" level before the second sense operation.

According to the embodiment, in the verify operation, the bus LBUS is brought into a floating state and thus the bus LBUS is influenced by capacitive coupling with the node SEN1. Thus, the voltage of the bus LBUS lowers in accordance with the voltage of the node SEN1 which is lowered by the first sense operation. Therefore, the result of the first sense operation can be stored in the latch circuit based on the voltage of the bus LBUS without performing strobing. In addition, the second sense operation can be performed continuously with the first sense operation without performing a process of resetting the voltage of the bus LBUS between the first and second sense operations. Therefore, according to the embodiment, the speed of the verify operation can be improved, as can be the speed of the write operation.

### 2 Others

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a bit line;
a memory cell transistor electrically coupled to the bit line; and
a sense amplifier module which reads data from the memory cell transistor via the bit line,
wherein:
the sense amplifier module includes:
a first node electrically connectable to the bit line; and
a second node capacitively couplable with the first node;
in a read operation of reading first data and second data continuously while applying a first voltage to a gate of the memory cell transistor, a voltage of the second node decreases with a decrease in a voltage of the first node by capacitive coupling between the first node and the second node in a first period that is continuous to a second period; and
the sense amplifier module is configured to:
determine the first data based on the voltage of the second node that is lowered in the first period; and
determine the second data based on the voltage of the first node that is lowered in the second period.

2. The semiconductor memory device of claim 1, wherein:
the sense amplifier module further includes a first transistor having a first end coupled to the first node and a second end coupled to the bit line; and
the sense amplifier module turns on the first transistor throughout the first period and the second period.

3. The semiconductor memory device of claim 2, wherein:
the first data is determined based on whether the voltage of the second node is maintained at a voltage that is higher than the second voltage in the first period; and
the second data is determined based on whether the voltage of the first node is maintained at a voltage that is higher than a fourth voltage in the second period.

4. The semiconductor memory device of claim 3, wherein:
the sense amplifier module further includes a first latch circuit including a second transistor having one end coupled to the second node; and
the sense amplifier module is configured to:
determine the first data by turning off the second transistor when the voltage of the second node is higher than the second voltage in the first period and by turning on the second transistor when the voltage of the second node is equal to or lower than the second voltage in the first period; and
store the determined first data in the first latch circuit.

5. The semiconductor memory device of claim 4, wherein a third voltage, which is obtained by adding a threshold voltage of the second transistor to the second voltage, is applied to a gate of the second transistor in the first period.

6. The semiconductor memory device of claim 5, wherein the sense amplifier module further includes:
a third transistor having one end coupled to the second node;
a fourth transistor having a gate coupled to the first node, one end coupled to the other end of the third transistor, and the other end coupled to the third node; and
a second latch circuit coupled to the second node.

7. The semiconductor memory device of claim 6, wherein:
in the read operation, after a lapse of the second period, the sense amplifier module is configured to:
turn on the third transistor to couple the second node and one end of the fourth transistor electrically; and
determine the second data by turning on the fourth transistor when the voltage of the first node is higher than the fourth voltage and by turning off the fourth transistor when the voltage of the first node is equal to or lower than the fourth voltage; and
store the determined second data in the second latch circuit.

8. The semiconductor memory device of claim 7, wherein the sense amplifier module is so configured that:
at first time when the second period ends, when the voltage of the second node is maintained higher than the second voltage, the voltage of the first node becomes higher than the fourth voltage; and
at the first time, when the voltage of the second node is equal to or lower than the second voltage, the voltage of the first node becomes equal to or lower than the fourth voltage.

9. The semiconductor memory device of claim 6, wherein in the read operation, before the first period, the sense amplifier module is configured to:
set the voltage of the second node at a fifth voltage that is higher than the voltage of the third node;
turn on the third transistor to couple the second node and one end of the fourth transistor electrically and to lower the voltage of the second node; and
store data corresponding to the voltage of the second node in the first latch circuit in advance.

10. The semiconductor memory device of claim 9, wherein a voltage that is lower than the third voltage is applied to the gate of the second transistor in the second period.

11. The semiconductor memory device of claim 1, wherein the capacitance coupling between the first node and the second node is caused by capacitance between interconnects.

12. The semiconductor memory device of claim 1, wherein the first node and the second node are coupled via a capacitive element.

13. The semiconductor memory device of claim 1, wherein the sense amplifier module uses the first data and the second data to determine whether to increase a threshold voltage of the memory cell transistor in a next program operation and to determine an amount of increase in the threshold voltage of the memory cell transistor when the threshold voltage of the memory cell transistor is increased.
